(19) United States
(12) Patent Application Publication
(10) Pub. No.: US 2014/0240029 A1
(43) Pub. Date: Aug. 28, 2014

(54) BRIDGE SWITCH CONTROL CIRCUIT AND METHOD OF OPERATING THE SAME

(71) Applicant: DELTA ELECTRONICS, INC., Taoyuan County (TW)

(72) Inventors: Te-Chih PENG, Taoyuan County (TW); Hsin-Chung NIU, Taoyuan County (TW)

(73) Assignee: DELTA ELECTRONICS, INC., Taoyuan County (TW)

(21) Appl. No.: 14/058,577

(22) Filed: Oct. 21, 2013

(30) Foreign Application Priority Data
Feb. 22, 2013 (TW) 102106125

(51) Int. Cl. H03K 3/013

(52) U.S. Cl. CPC H03K 3/013
USPC 327/423

(57) ABSTRACT

A method of operating a bridge switch control circuit is disclosed for controlling at least one pair of complementary switches. First, a first driving signal, a second driving signal, a first latching signal, and a second latching signal are provided. The first driving signal and the second driving signal drive the complementary switches. Afterward, it is to judge whether the first driving signal triggers one of the complementary switches by a rising-edge manner. If YES, the first latching signal is controlled at a high-level status and the second latching signal is simultaneously controlled at a low-level status. Afterward, it is to judge whether the second driving signal triggers the other of the complementary switches by a rising-edge manner. If YES, the second latching signal is controlled at a high-level status and the first latching signal is simultaneously controlled at a low-level status.

### BACKGROUND

1. Technical Field

The present disclosure relates generally to a bridge switch control circuit and a method of operating the same, and more particularly to a bridge switch control circuit with an interleaved switching function and a method of operating the same.

2. Description of Related Art

In the switching circuits for power switches, because the non-ideal turn-on delay and turn-off delay, the power switches would not immediately turned on or turned off when driven by the control signals. In order to prevent the short through operation of two switches in the same leg, dead times are usually provided. In addition, because the dead time is implemented by delaying a time interval after the power switch is changed from turned-off to turned-on, the delay time is associated with the switching speed.

Reference is made to FIG. 1A which is a circuit diagram of a related art half-bridge circuit architecture. For convenience, a converter with synchronous rectifying control is exemplified for further demonstration. The converter has a transformer with two switch elements at a secondary side thereof. The two switch elements can be MOSFETs and which are a first switch Q1 and a second switch Q2. Especially, the first switch Q1 and the second switch Q2 are one pair of complementary switches. That is when the first switch Q1 is turned on, the second switch Q2 is turned off, whereas when the first switch Q1 is turned off, the second switch Q2 is turned on. Reference is made to FIG. 1B which is a schematic view of a related art dead time scheme. As mentioned above, a dead time td is provided between the two switches which are turned on and turned off, thus preventing the first switch Q1 and the second switch Q2 from a short through operation because the first switch Q1 and the second switch Q2 are simultaneously turned on. As shown in FIG. 1B, the dead times td are provided between the time t1 and the time t2, between the time t3 and the time t4, and between the time t5 and the time t6. If the dead time td is shortened, the effective duty cycle is increased so that conversion efficiency is increased, but the short though operation would easily occur because of noise disturbance or non-ideal characteristics of the switch elements. On the contrary, if the dead time td is lengthened, the short though operation would not easily occur, but the effective duty cycle is reduced so that the conversion efficiency is reduced. Reference is made to FIG. 1C which is another schematic view of a related art dead time scheme. In order to prevent the short through operation of the first switch Q1 and the second switch Q2, a protection mechanism (minimum on time mechanism) is provided. As shown in FIG. 1C, a noise disturbance Sₙ occurs between the time t3 and the time t4, a first driving signal S_{g1} for driving the first switch Q1 is compulsorily closed. Until the noise disturbance Sₙ is eliminated, the minimum on time mechanism starts and the previous first driving signal S_{g1} is re-worked to continue the unfinished turned-on operation. However, when a second driving signal S_{g2} is turned on, the first driving signal S_{g1} and the second driving signal S_{g2} are simultaneously turned on to occur the short through operation so that the switch elements are permanently damaged and the circuit reliability is significantly reduced.

Accordingly, it is desirable to provide a bridge switch control circuit and a method of operating the same that are applied to bridge-type circuits (including half-bridge and full-bridge circuits) so as to prevent the short through operation of two switch loops, increase circuit reliability, and enhance noise immunity.

### SUMMARY

An object of the present disclosure is to provide a method of operating a bridge switch control circuit to solve the above-mentioned problems. Accordingly, the method of operating the bridge switch control circuit includes following steps: (a) a first driving signal, a second driving signal, a first latching signal, and a second latching signal are provided, wherein the first driving signal and the second driving signal are configured to drive at least one pair of complementary switches; (b) it is to judge whether the first driving signal triggers one of the complementary switches by a rising-edge manner; (c) the first latching signal is controlled at a high-level status and simultaneously the second latching signal is controlled at a low-level status when the first driving signal triggers one of the complementary switches by the rising-edge manner; (d) it is to judge whether the second driving signal triggers the other of the complementary switches by a rising-edge manner; and (e) the second latching signal is controlled at a high-level status and simultaneously the first latching signal is controlled at a low-level status when the second driving signal triggers the other of the complementary switches by the rising-edge manner.

Another object of the present disclosure is to provide a bridge switch control circuit to solve the above-mentioned problems. Accordingly, the bridge switch control circuit includes a bridge circuit and a control module. The bridge circuit includes at least one pair of complementary switches, and the at least one pair of complementary switches are controlled by two driving signals. The control module includes a judgment unit and a latching unit. The judgment unit judges turned-on and turned-off conditions of the at least one pair of complementary switches and correspondingly produces two output signals according to drain-source voltages of the at least one pair of complementary switches. The latching unit receives the two output signals and provides latching operations to correspondingly output two latching signals according to signal levels of the two output signals. When the driving signal drives one of the complementary switches by the rising-edge manner, the corresponding latching signal is controlled at a high-level status and the other latching signal is simultaneously controlled at a low-level status so that the one of the complementary switches is turned on and the other of the complementary switches is turned off, thus preventing the at least one pair of complementary switches from a short through operation.

It is to be understood that both the foregoing general description and the following detailed description are exemplary, and are intended to provide further explanation of the present disclosure as claimed. Other advantages and features of the present disclosure will be apparent from the following description, drawings and claims.

### BRIEF DESCRIPTION OF DRAWINGS

The features of the present disclosure believed to be novel are set forth with particularity in the appended claims. The present disclosure itself, however, may be best understood by reference to the following detailed description of the present disclosure, which describes an exemplary embodiment of the present disclosure, taken in conjunction with the accompanying drawings, in which:

FIG. 1A is a circuit diagram of a related art half-bridge circuit architecture;

FIG. 1B is a schematic view of a related art dead time scheme;

FIG. 1C is another schematic view of a related art dead time scheme;

FIG. 2 is a flowchart of a method of operating a bridge switch control circuit with an interleaved switching function according to the present disclosure;

FIG. 3A is a schematic signal waveform graph of the operation method according to a first embodiment of the present disclosure;

FIG. 3B is a schematic signal waveform graph of the operation method according to a second embodiment of the present disclosure;

FIG. 3C is a schematic signal waveform graph of the operation method according to a third embodiment of the present disclosure;

FIG. 3D is a schematic signal waveform graph of the operation method according to a fourth embodiment of the present disclosure;

FIG. 4A is a schematic circuit block diagram of the bridge switch control circuit according to a first embodiment of the present disclosure;

FIG. 4B is a schematic circuit block diagram of the bridge switch control circuit according to a second embodiment of the present disclosure; and

FIG. 5 is a circuit diagram of a latching unit of the bridge switch control circuit according to the present disclosure.

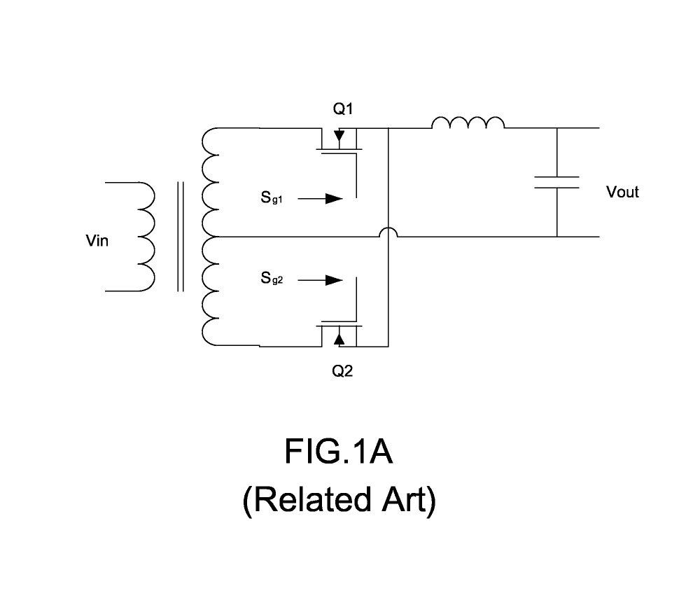

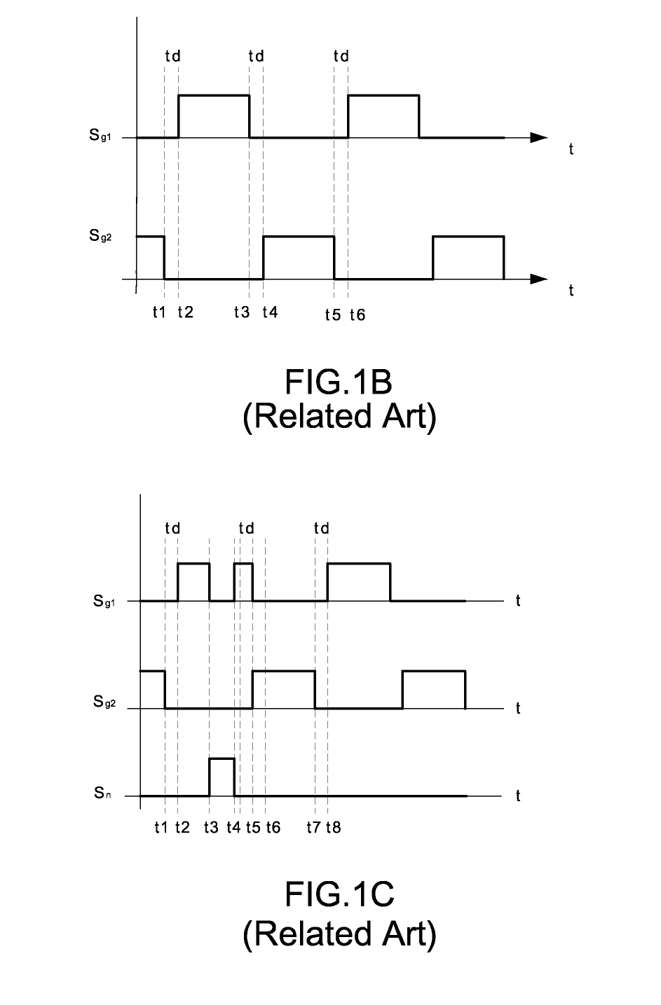

### DETAILED DESCRIPTION

Reference will now be made to the drawing figures to describe the present invention in detail.

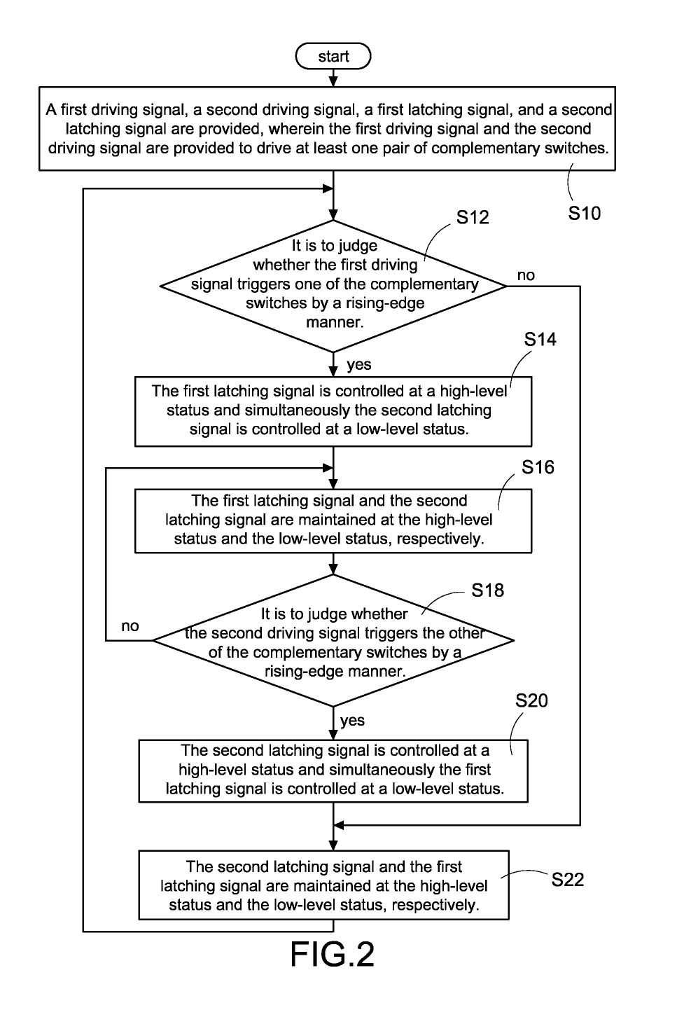

Reference is made to FIG. 2 which is a flowchart of a method of operating a bridge switch control circuit with an interleaved switching function according to the present disclosure. The method of operating the bridge switch control circuit includes following steps: First, a first driving signal S_{GD1}, a second driving signal S_{GD2}, a first latching signal S_{LH1}, and a second latching signal S_{LH2} are provided, wherein the first driving signal S_{GD1} and the second driving signal S_{GD2} are provided to drive at least one pair of complementary switches (S10). Afterward, it is to judge whether the first driving signal S_{GD1} triggers one of the complementary switches by a rising-edge manner (S12). The first latching signal S_{LH1} is controlled at a high-level status and simultaneously the second latching signal S_{LH2} is controlled at a low-level status when the first driving signal S_{GD1} triggers one of the complementary switches by the rising-edge manner (S14), and then the first latching signal S_{LH1} and the second latching signal S_{LH2} are maintained at the high-level status and the low-level status, respectively (S16). Afterward, it is to judge whether the second driving signal S_{GD2} triggers the other of the complementary switches by a rising-edge manner (S18). The second latching signal S_{LH2} is controlled at a high-level status and simultaneously the first latching signal S_{LH1} is controlled at a low-level status when the second driving signal S_{GD2} triggers the other of the complementary switches by the rising-edge manner (S20), and then the second latching signal S_{LH2} and the first latching signal S_{LH1} are maintained at the high-level status and the low-level status, respectively (S22). In the step (S12), if the first driving signal S_{GD1} does not trigger one of the complementary switches by the rising-edge manner, the step (S22) is executed, that is, the second latching signal S_{LH2} and the first latching signal S_{LH1} are maintained at the high-level status and the low-level status, respectively. In the step (S18), if the second driving signal S_{GD2} does not trigger the other of the complementary switches by the rising-edge manner, the step (S16) is executed, that is, the first latching signal S_{LH1} and the second latching signal S_{LH2} are maintained at the high-level status and the low-level status, respectively. The detailed operation of the bridge switch control circuit will be described hereinafter as follows.

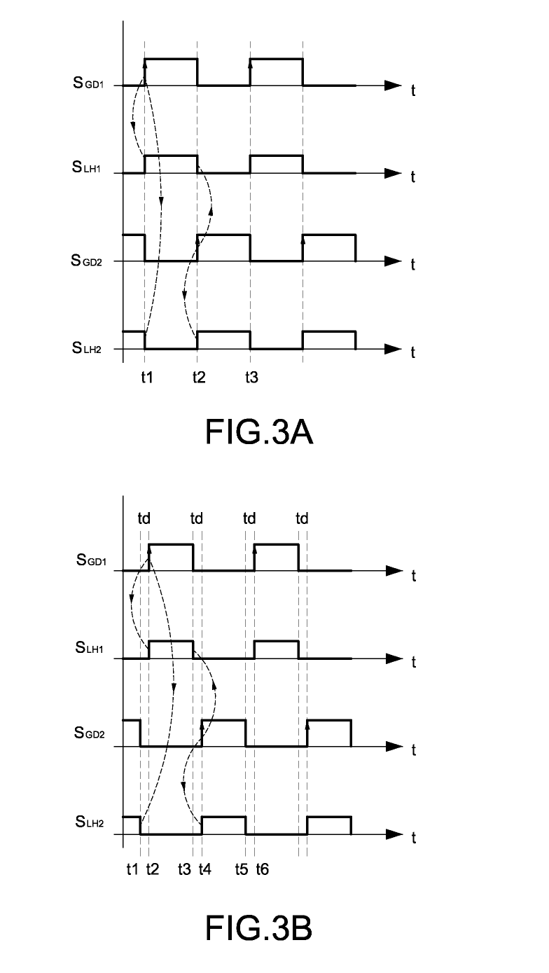

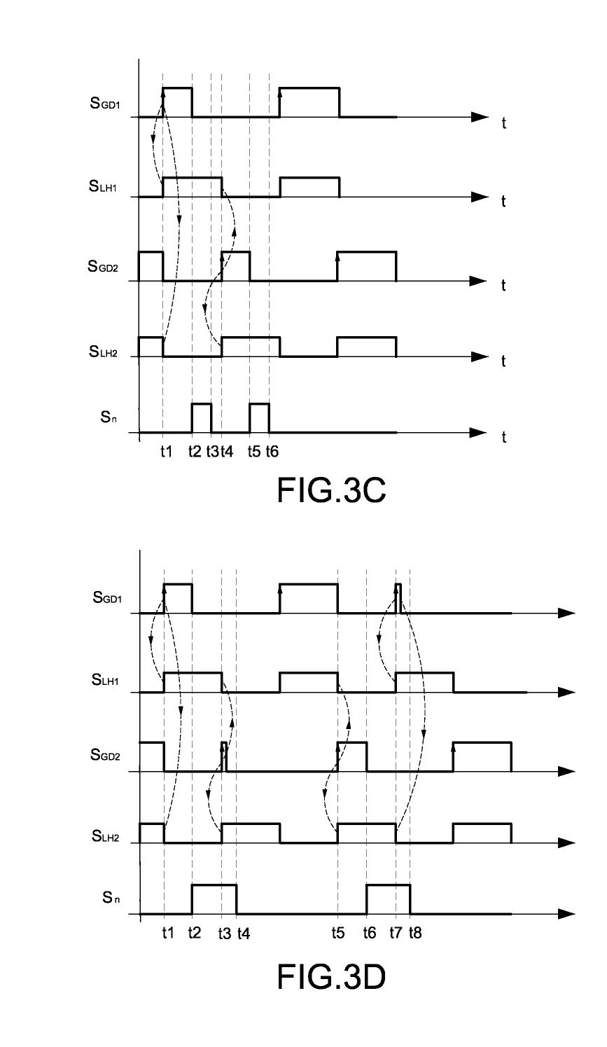

Reference is made to FIG. 3A which is a schematic signal waveform graph of the operation method according to a first embodiment of the present disclosure. At the time t1, because the first driving signal S_{GD1} drives one of the complementary switches by the rising-edge manner, the first latching signal S_{LH1} is changed from the low-level status to the high-level status and the second latching signal S_{LH2} is simultaneously changed from the high-level status to the low-level status. At the time t2, because the second driving signal S_{GD2} drives the other of the complementary switches by the rising-edge manner, the second latching signal S_{LH2} is changed from the low-level status to the high-level status and the first latching signal S_{LH1} is simultaneously changed from the high-level status to the low-level status. In particular, each of the complementary switches is a metal-oxide-semiconductor field effect transistor (MOSFET) or an insulated gate bipolar transistor (IGBT). However, the embodiments are only exemplified but are not intended to limit the scope of the present disclosure.

In addition, if the first driving signal S_{GD1} does not trigger one of the complementary switches by the rising-edge manner (before the time t1, or between the time t2 and the time t3, the first driving signal S_{GD1} is at the low-level status), the second latching signal S_{LH2} and the first latching signal S_{LH1} are maintained at the high-level status and the low-level status, respectively. If the second driving signal S_{GD2} does not trigger the other of the complementary switches by the rising-edge manner (before the time t1, or between the time t2 and the time t3, the second driving signal S_{GD2} is at the low-level status), the first latching signal S_{LH1} and the second latching signal S_{LH2} are maintained at the high-level status and the low-level status, respectively.

Reference is made to FIG. 3B which is a schematic signal waveform graph of the operation method according to a second embodiment of the present disclosure. The major difference between the second embodiment and the first embodiment is that dead times are provided between the level change of the first driving signal S_{GD1} and the second driving signal S_{GD2} in the second embodiment. As shown in FIG. 3B, a dead time td is provided between the time t1 and the time t2, between the time t3 and the time t4, and between the time t5 and the time 6, respectively. At the time t2, because the first driving signal S_{GD1} drives one of the complementary switches by the rising-edge manner, the first latching signal S_{LH1} is changed from the low-level status to the high-level status and the second latching signal S_{LH2} is simultaneously changed from the high-level status to the low-level status. Especially, because of the provided dead time td, the second latching signal S_{LH2} is changed from the high-level status to the low-level status at the time t1. When the dead time td is started, if the second latching signal S_{LH2} cannot be changed to the low-level status because of noise disturbance or non-ideal characteristics of the switch elements, the first driving signal S_{GD1} drives one of the complementary switches by the rising-edge manner to control the second latching signal S_{LH2} is changed from the high-level status to the low-level status. The detailed operation of the bridge switch control circuit with respect to noise disturbance will be described hereinafter as follows.

Similarly, at the time t4, because the second driving signal S_{GD2} drives the other of the complementary switches by the rising-edge manner, the second latching signal S_{LH2} is changed from the low-level status to the high-level status and the first latching signal S_{LH1} is simultaneously changed from the high-level status to the low-level status. Especially, because of the provided dead time td, the first latching signal S_{LH1} is changed from the high-level status to the low-level status at the time t3. When the dead time td is started, if the first latching signal S_{LH1} cannot be changed to the low-level status because of noise disturbance or non-ideal characteristics of the switch elements, the second driving signal S_{GD2} drives the other of the complementary switches by the rising-edge manner to control the first latching signal S_{LH1} is changed from the high-level status to the low-level status. The detailed operation of the bridge switch control circuit with respect to noise disturbance will be described hereinafter as follows.

In addition, if the first driving signal S_{GD1} does not trigger one of the complementary switches by the rising-edge manner (before the time t1, or between the time t4 and the time t5, the first driving signal S_{GD1} is at the low-level status), the second latching signal S_{LH2} and the first latching signal S_{LH1} are maintained at the high-level status and the low-level status, respectively. If the second driving signal S_{GD2} does not trigger the other of the complementary switches by the rising-edge manner (between the time t2 and the time t3, or after the time t6, the second driving signal S_{GD2} is at the low-level status), the first latching signal S_{LH1} and the second latching signal S_{LH2} are maintained at the high-level status and the low-level status, respectively.

Reference is made to FIG. 3C which is a schematic signal waveform graph of the operation method according to a third embodiment of the present disclosure. The major difference between the third embodiment and the first embodiment is that noises Sₙ are generated in the third embodiment. As shown in FIG. 3C, a noise Sₙ is generated between the time t2 and the time t3 and between the time t5 and the time t6, respectively. At the time t1, because the first driving signal S_{GD1} drives one of the complementary switches by the rising-edge manner, the first latching signal S_{LH1} is changed from the low-level status to the high-level status and the second latching signal S_{LH2} is simultaneously changed from the high-level status to the low-level status. At the time t2, because of the generated noise Sₙ, the first driving signal S_{GD1} is compulsorily changed from the high-level status to the low-level status. At this time, the first latching signal S_{LH1} is still maintained at the high-level status so that the first driving signal S_{GD1} is latched and cannot be triggered to change to the high-level status by the rising-edge manner. At the time t3, the noise Sₙ is eliminated. Because the first latching signal S_{LH1} is still maintained at the high-level status so that the first driving signal S_{GD1} is still latched. Until the time t4, because the second driving signal S_{GD2} drives the other of the complementary switches by the rising-edge manner, the second latching signal S_{LH2} is changed from the low-level status to the high-level status and the first latching signal S_{LH1} is simultaneously changed from the high-level status to the low-level status. At the time t5, because of the generated noise Sₙ, the second driving signal S_{GD2} is compulsorily changed from the high-level status to the low-level status. At this time, the second latching signal S_{LH2} is still maintained at the high-level status so that the second driving signal S_{GD2} is latched and cannot be triggered to change to the high-level status by the rising-edge manner. At the time t6, the noise Sₙ is eliminated. Because the second latching signal S_{LH2} is still maintained at the high-level status so that the second driving signal S_{GD2} is still latched.

Reference is made to FIG. 3D which is a schematic signal waveform graph of the operation method according to a fourth embodiment of the present disclosure. The major difference between the fourth embodiment and the third embodiment is that noises Sₙ are generated in the fourth embodiment and the duration of the noises Sₙ are longer. As shown in FIG. 3D, a noise Sₙ is generated between the time t2 and the time t4 and between the time t6 and the time t8, respectively. At the time t1, because the first driving signal S_{GD1} drives one of the complementary switches by the rising-edge manner, the first latching signal S_{LH1} is changed from the low-level status to the high-level status and the second latching signal S_{LH2} is simultaneously changed from the high-level status to the low-level status. At the time t2, because of the generated noise Sₙ, the first driving signal S_{GD1} is compulsorily changed from the high-level status to the low-level status. At this time, the first latching signal S_{LH1} is still maintained at the high-level status so that the first driving signal S_{GD1} is latched and cannot be triggered to change to the high-level status by the rising-edge manner. At the time t3, because the second driving signal S_{GD2} drives the other of the complementary switches by the rising-edge manner, the second latching signal S_{LH2} is changed from the low-level status to the high-level status and the first latching signal S_{LH1} is simultaneously changed from the high-level status to the low-level status. Because the noise Sₙ is still present, however, the second driving signal S_{GD2} is immediately changed to the low-level status after the second driving signal S_{GD2} drives the other of the complementary switches by the rising-edge manner. Because the second latching signal S_{LH2} is still maintained at the high-level status so that the second driving signal S_{GD2} is still latched and cannot be triggered to change to the high-level status by the rising-edge manner. At the time t4, the noise Sₙ is eliminated. Because the second latching signal S_{LH2} is still maintained at the high-level status so that the second driving signal S_{GD2} is still latched.

At the time t5, because the second driving signal S_{GD2} drives the other of the complementary switches by the rising-edge manner, the second latching signal S_{LH2} is changed from the low-level status to the high-level status and the first latching signal S_{LH1} is simultaneously changed from the high-level status to the low-level status. At the time t6, because of the generated noise Sₙ, the second driving signal S_{GD2} is compulsorily changed from the high-level status to the low-level status. At this time, the second latching signal S_{LH2} is still maintained at the high-level status so that the second driving signal S_{GD2} is latched and cannot be triggered to change to the high-level status by the rising-edge manner. At the time t7, because the first driving signal S_{GD1} drives one of the complementary switches by the rising-edge manner, the first latching signal S_{LH1} is changed from the low-level status to the high-level status and the second latching signal S_{LH2} is simultaneously changed from the high-level status to the low-level status. Because the noise Sₙ is still present, however, the first driving signal S_{GD1} is immediately changed to the low-level status after the first driving signal S_{GD1} drives one of the complementary switches by the rising-edge manner. Because the first latching signal S_{LH1} is still maintained at the high-level status so that the first driving signal S_{GD1} is still latched and cannot be triggered to change to the high-level status by the rising-edge manner. At the time t8, the noise Sₙ is eliminated. Because the first latching signal S_{LH1} is still maintained at the high-level status so that the first driving signal S_{GD1} is still latched.

According to the detailed operations of the above-mentioned embodiments, the first driving signal S_{GD1} drives one of the complementary switches by the rising-edge manner to control the first latching signal S_{LH1} changed from the low-level status to the high-level status so that the first driving signal S_{GD1} is latched and the second latching signal S_{LH2} is simultaneously changed from the high-level status to the low-level status to unlatch the second driving signal S_{GD2}. Similarly, the second driving signal S_{GD2} drives the other of the complementary switches by the rising-edge manner to control the second latching signal S_{LH2} changed from the low-level status to the high-level status so that the second driving signal S_{GD2} is latched and the first latching signal S_{LH1} is simultaneously changed from the high-level status to the low-level status to unlatch the first driving signal S_{GD1}. Accordingly, the first driving signal S_{GD1} and the second driving signal S_{GD2} are provided to control the latching signals to implement the interleaved switching control. When one switch is turned on by the first driving signal S_{GD1}, the other switch driven by the second driving signal S_{GD2} is turned off. On the contrary, when one switch is turned on by the second driving signal S_{GD2}, the other switch driven by the first driving signal S_{GD1} is turned off. Accordingly, the two switches cannot be simultaneously turned on to prevent the short through operation of two switch loops.

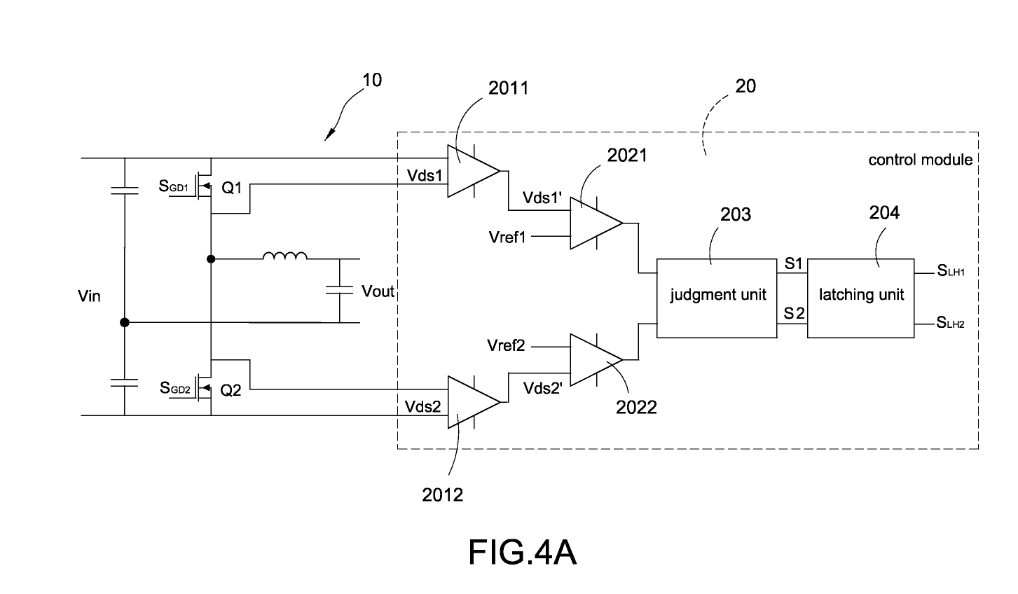

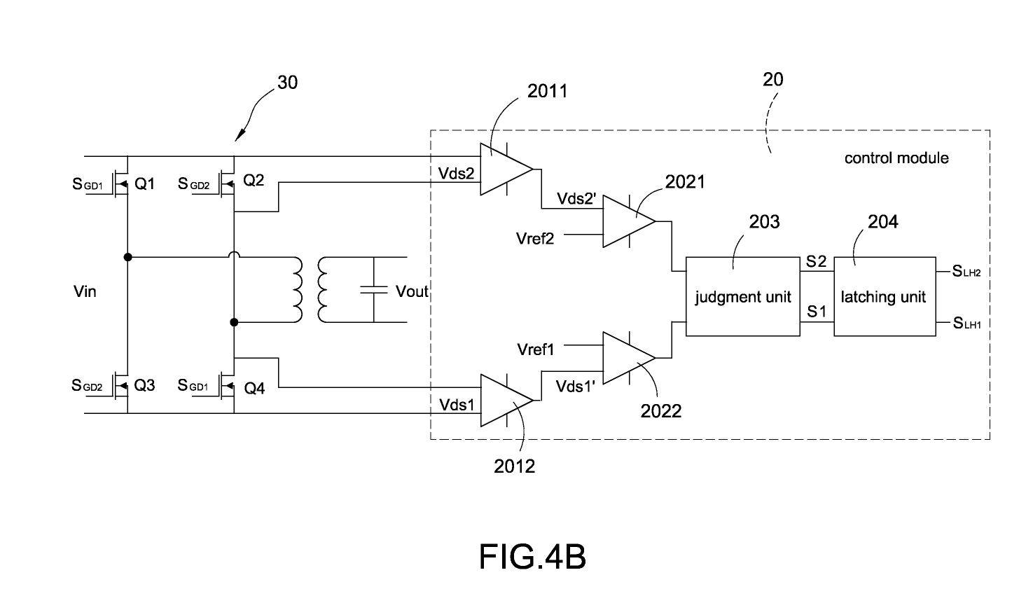

In following contents, corresponding circuits are provided to explain the method of operating the bridge switch control circuit. Reference is made to FIG. 4A which is a schematic circuit block diagram of the bridge switch control circuit according to a first embodiment of the present disclosure. In the first embodiment, the bridge switch control circuit includes a half-bridge circuit 10 and a control module 20. The bridge switch control circuit has one pair of complementary switches, and the two switches are a first switch Q1 and a second switch Q2, respectively. In particular, each of the complementary switches is a metal-oxide-semiconductor field effect transistor (MOSFET) or an insulated gate bipolar transistor (IGBT). However, the embodiments are only exemplified but are not intended to limit the scope of the present disclosure. The first driving signal S_{GD1} and the second driving signal S_{GD2} are provided to drive the first switch Q1 and the second switch Q2, respectively. The control module 20 includes a first voltage amplifying unit 2011, a second voltage amplifying unit 2012, a first comparison unit 2021, a second comparison unit 2022, a judgment unit 203, and a latching unit 204. The first voltage amplifying unit 2011 receives a drain-source voltage Vds1 of the first switch Q1 and then amplifies the drain-source voltage Vds1 to output an amplified drain-source voltage Vds1′. Similarly, the second voltage amplifying unit 2012 receives a drain-source voltage Vds2 of the second switch Q2 and then amplifies the drain-source voltage Vds2 to output an amplified drain-source voltage Vds2′. Afterward, the amplified drain-source voltage Vds1′ is compared to a first reference voltage Vref1 by the first comparison unit 2021. If the amplified drain-source voltage Vds1′ is greater than the first reference voltage Vref1, the first comparison unit 2021 produces a high-level signal, that is the first switch Q1 is turned on by the first driving signal S_{GD1}, whereas the first comparison unit 2021 produces a low-level signal. The amplified drain-source voltage Vds2′ is compared to a second reference voltage Vref2 by the second comparison unit 2022. If the amplified drain-source voltage Vds2′ is greater than the second reference voltage Vref2, the second comparison unit 2022 produces a high-level signal, that is the second switch Q2 is turned on by the second driving signal S_{GD2}, whereas the second comparison unit 2022 produces a low-level signal.

The judgment unit 203 receives the signals of the first comparison unit 2021 and the second comparison unit 2022, judges the turned-on and turned-off conditions of the first switch Q1 and the second switch Q2, and outputs a first output signal S1 and a second output signal S2, respectively. Especially, the first output signal S1 is high-level that means the first driving signal S_{GD1} drives the first switch Q1 by the rising-edge manner, namely the first driving signal S_{GD1} is changed from the low-level status to the high-level status; the second output signal S2 is high-level that means the second driving signal S_{GD2} drives the second switch Q2 by the rising-edge manner, namely the second driving signal S_{GD2} is changed from the low-level status to the high-level status. The latching unit 204 receives the first output signal S1 and the second output signal S2 and provides latching operations according to signal levels of the first output signal S1 and the second output signal S2, thus outputting the first latching signal S_{LH1} and the second latching signal S_{LH2}. As mentioned above, when the first driving signal S_{GD1} is at the high-level status and the second driving signal S_{GD2} is at the low-level status, the first latching signal S_{LH1} is controlled at the high-level status and the second latching signal S_{LH2} is simultaneously controlled at the low-level status so that the first switch Q1 is turned on and the second switch Q2 is turned off to prevent the first switch Q1 and the second switch Q2 from a short through operation. On the contrary, when the second driving signal S_{GD2} is at the high-level status and the first driving signal S_{GD1} is at the low-level status, the second latching signal S_{LH2} is controlled at the high-level status and the first latching signal S_{LH1} is simultaneously controlled at the low-level status so that the second switch Q2 is turned on and the first switch Q1 is turned off to prevent the second switch Q2 and the first switch Q1 from a short through operation.

Reference is made to FIG. 4B which is a schematic circuit block diagram of the bridge switch control circuit according to a second embodiment of the present disclosure. The major difference between the second embodiment and the first embodiment is that the bridge switch control circuit in the second embodiment includes a full-bridge circuit 30 and a control module 20. The bridge switch control circuit has two pairs of complementary switches, and the four switches are a first switch Q1, a second switch Q2, a third switch Q3, and a fourth switch Q4, respectively. In particular, the first switch Q1 and the fourth switch Q4 are simultaneously turned on or turned off to form a first switch assembly Qa1; the second switch Q2 and the third switch Q3 are simultaneously turned on or turned off to form a second switch assembly Qa2. The first driving signal S_{GD1} and the second driving signal S_{GD2} are provided to drive the first switch assembly Qa1 and the second switch assembly Qa2, respectively. Especially, the difference between the two embodiments is described as follows but the same content is omitted here for conciseness.

The first voltage amplifying unit 2011 receives a drain-source voltage Vds1 of the first switch Q1 or the fourth switch Q4 and then amplifies the drain-source voltage Vds1 to output an amplified drain-source voltage Vds1′. Similarly, the second voltage amplifying unit 2012 receives a drain-source voltage Vds2 of the second switch Q2 or the third switch Q3 and then amplifies the drain-source voltage Vds2 to output an amplified drain-source voltage Vds2′. Afterward, the amplified drain-source voltage Vds1′ is compared to a first reference voltage Vref1 by the first comparison unit 2021. When the amplified drain-source voltage Vds1′ is greater than or equal to the first reference voltage Vref1, the first comparison unit 2021 outputs a high-level signal; whereas the amplified drain-source voltage Vds1′ is less than the first reference voltage Vref1, the first comparison unit 2021 outputs a low-level signal. The amplified drain-source voltage Vds2′ is compared to a second reference voltage Vref2 by the second comparison unit 2022. When the amplified drain-source voltage Vds2′ is greater than or equal to the second reference voltage Vref2, the second comparison unit 2022 outputs a high-level signal; whereas the amplified drain-source voltage Vds2′ is less than the second reference voltage Vref2, the second comparison unit 2022 outputs a low-level signal.

The judgment unit 203 receives the signals of the first comparison unit 2021 and the second comparison unit 2022, judges the turned-on and turned-off conditions of the first switch assembly Qa1 and the second switch assembly Qa2, and outputs a first output signal S1 and a second output signal S2, respectively. Especially, the first output signal S1 is high-level that means the first driving signal S_{GD1} drives the fourth switch Q4 by the rising-edge manner, namely the first driving signal S_{GD1} is changed from the low-level status to the high-level status; the second output signal S2 is high-level that means the second driving signal S_{GD2} drives the second switch Q2 by the rising-edge manner, namely the second driving signal S_{GD2} is changed from the low-level status to the high-level status. The latching unit 204 receives the first output signal S1 and the second output signal S2 and provides latching operations according to signal levels of the first output signal S1 and the second output signal S2, thus outputting the first latching signal S_{LH1} and the second latching signal S_{LH2}. As mentioned above, when the first driving signal S_{GD1} is at the high-level status and the second driving signal S_{GD2} is at the low-level status, the first latching signal S_{LH1} is controlled at the high-level status and the second latching signal S_{LH2} is simultaneously controlled at the low-level status so that the fourth switch Q4 is turned on and the second switch Q2 is turned off to prevent the fourth switch Q4 and the second switch Q2 from a short through operation. On the contrary, when the second driving signal S_{GD2} is at the high-level status and the first driving signal S_{GD1} is at the low-level status, the second latching signal S_{LH2} is controlled at the high-level status and the first latching signal S_{LH1} is simultaneously controlled at the low-level status so that the second switch Q2 is turned on and the fourth switch Q4 is turned off to prevent the second switch Q2 and the fourth switch Q4 from a short through operation. The detailed operation of the latching unit 204 will be described hereinafter as follows.

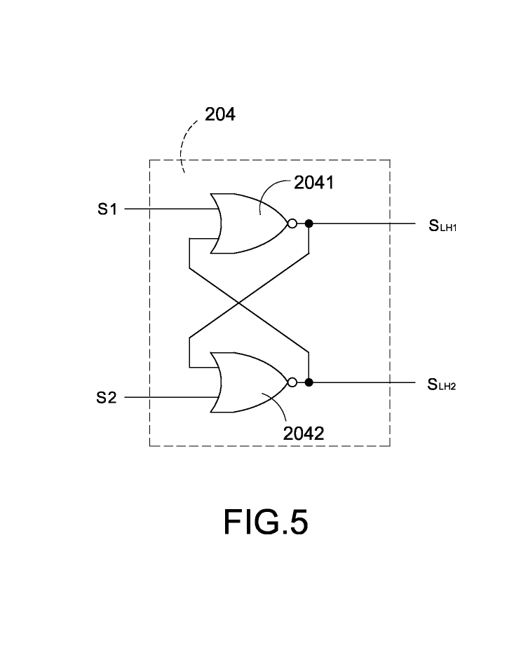

Reference is made to FIG. 5 which is a circuit diagram of a latching unit of the bridge switch control circuit according to the present disclosure. The latching unit 204 can be a NOR R-S latch, NAND R-S latch, D latch, or a latch circuit that is composed of logic gates. For convenience, the R-S latch and the half-bridge circuit 10 shown in FIG. 4A are exemplified for further demonstration. The latching unit 204 is formed by connecting two NOR gates 2041, 2042. When the first driving signal S_{GD1} drives the first switch Q1 by the rising-edge manner, the first output signal S1 is high-level and the second output signal S2 is low-level so that the first latching signal S_{LH1} is outputted at the high-level status and the second latching signal S_{LH2} is outputted at the low-level status. If the first driving signal S_{GD1} does not trigger the first switch Q1 by the rising-edge manner, the first output signal S1 is low-level and the second output signal S2 is still low-level so that the first latching signal S_{LH1} and the second latching signal S_{LH2} are maintained at the previous output levels. Until the second driving signal S_{GD2} drives the second switch Q2 by the rising-edge manner, the second output signal S2 is high-level and the first output signal S1 is low-level so that the second latching signal S_{LH2} is outputted at the high-level status and the first latching signal S_{LH1} is outputted at the low-level status. If the second driving signal S_{GD2} does not trigger the second switch Q2 by the rising-edge manner, the second output signal S2 is low-level and the first output signal S1 is still low-level so that the second latching signal S_{LH2} and the first latching signal S_{LH1} are maintained at the previous output levels.

Accordingly, the first driving signal S_{GD1} and the second driving signal S_{GD2} are provided to control the latching signals to implement the interleaved switching control. When one switch is turned on by the first driving signal S_{GD1}, the other switch driven by the second driving signal S_{GD2} is turned off. On the contrary, when one switch is turned on by the second driving signal S_{GD2}, the other switch driven by the first driving signal S_{GD1} is turned off. Accordingly, the two switches cannot be simultaneously turned on to prevent the short through operation of two switch loops.

In conclusion, the present disclosure has following advantages:

1. The bridge switch control circuit with the interleaved switching function and the method of operating the same are used to increase the on duty of the switches, thus increasing efficiency of the bridge switch control circuit;

2. The interleaved switching control is provided so that the two switch loops are controlled from a short through operation;

3. When a switch loop is abnormal because of noise disturbance or non-ideal characteristics of the switch, the abnormal switch loop is latched. Until the abnormal condition is eliminated, the abnormal switch loop is unlatched and then the next switching control is executed, thus increasing circuit reliability and enhancing noise immunity;

4. The bridge switch control circuit with the interleaved switching function and the method of operating the same can be applied to all of bridge-type circuits (including half-bridge and full-bridge circuits), such as the bridge rectifying circuit, but not limited;

5. The bridge switch control circuit with the interleaved switching function and the method of operating the same are used to save costs of installing the dead time peripheral circuits; and

6. The bridge switch control circuit with the interleaved switching function is used to significantly shorten design time of products and increase efficiency of developing projects.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A method of operating a bridge switch control circuit, comprising following steps:
(a) providing a first driving signal, a second driving signal, a first latching signal, and a second latching signal, wherein the first driving signal and the second driving signal are configured to drive at least one pair of complementary switches;
(b) judging whether the first driving signal triggers one of the complementary switches by a rising-edge manner;
(c) controlling the first latching signal at a high-level status and simultaneously controlling the second latching signal at a low-level status when the first driving signal triggers one of the complementary switches by the rising-edge manner;
(d) judging whether the second driving signal triggers the other of the complementary switches by a rising-edge manner; and
(e) controlling the second latching signal at a high-level status and simultaneously controlling the first latching signal at a low-level status when the second driving signal triggers the other of the complementary switches by the rising-edge manner.

2. The method of operating the bridge switch control circuit in claim 1, wherein in the step (c), the first latching signal and the second latching signal are maintained at the low-level status and the high-level status, respectively, when the first driving signal does not trigger one of the complementary switches by the rising-edge manner; in the step (e), the first latching signal and the second latching signal are maintained at the high-level status and the low-level status, respectively, when the second driving signal does not trigger the other of the complementary switches by the rising-edge manner.

3. The method of operating the bridge switch control circuit in claim 2, wherein the one pair of the complementary switches are configured to form a half-bridge architecture, the two switches are a first switch and a second switch; the first driving signal and the second driving signal are configured to drive the first switch and the second switch, respectively; when the first driving signal is at a high-level status and the second driving signal is at a low-level status, the first latching signal is controlled at the high-level status and the second latching signal is simultaneously controlled at the low-level status so as to turn on the first switch and turn off the second switch, thus preventing the first switch and the second switch from a short through operation.

4. The method of operating the bridge switch control circuit in claim 2, wherein the one pair of the complementary switches are configured to form a half-bridge architecture, the two switches are a first switch and a second switch; the first driving signal and the second driving signal are configured to drive the first switch and the second switch, respectively; when the second driving signal is at a high-level status and the first driving signal is at a low-level status, the second latching signal is controlled at the high-level status and the first latching signal is simultaneously controlled at the low-level status so as to turn on the second switch and turn off the first switch, thus preventing the first switch and the second switch from a short through operation.

5. The method of operating the bridge switch control circuit in claim 2, wherein the two pairs of the complementary switches are configured to form a full-bridge architecture, the four switches are a first switch, a second switch, a third switch, and a fourth switch; the first switch and the fourth switch are simultaneously turned on or turned off to form a first switch assembly, the second switch and the third switch are simultaneously turned on or turned off to form a second switch assembly; the first driving signal and the second driving signal are configured to drive the first switch assembly and the second switch assembly, respectively; when the first driving signal is at a high-level status and the second driving signal is at a low-level status, the first latching signal is controlled at the high-level status and the second latching signal is simultaneously controlled at the low-level status so as to turn on the first switch assembly and turn off the second switch assembly, thus preventing the first switch assembly and the second switch assembly from a short through operation.

6. The method of operating the bridge switch control circuit in claim 2, wherein the two pairs of the complementary switches are configured to form a full-bridge architecture, the four switches are a first switch, a second switch, a third switch, and a fourth switch; the first switch and the fourth switch are simultaneously turned on or turned off to form a first switch assembly, the second switch and the third switch are simultaneously turned on or turned off to form a second switch assembly; the first driving signal and the second driving signal are configured to drive the first switch assembly and the second switch assembly, respectively; when the second driving signal is at a high-level status and the first driving signal is at a low-level status, the second latching signal is controlled at the high-level status and the first latching signal is simultaneously controlled at the low-level status so as to turn on the second switch assembly and turn off the first switch assembly, thus preventing the first switch assembly and the second switch assembly from a short through operation.

7. The method of operating the bridge switch control circuit in claim 1, wherein dead times are provided between the at least one pair of complementary switches which are turned on and turned off.

8. The method of operating the bridge switch control circuit in claim 1, wherein each of the complementary switches is a metal-oxide-semiconductor field effect transistor (MOSFET) or an insulated gate bipolar transistor (IGBT).

9. A bridge switch control circuit comprising:
a bridge circuit comprising at least one pair of complementary switches, and the at least one pair of complementary switches are controlled by two driving signals; and
a control module comprising:
a judgment unit configured to judge turned-on and turned-off conditions of the at least one pair of complementary switches and correspondingly produce two output signals according to drain-source voltages of the at least one pair of complementary switches; and
a latching unit configured to receive the two output signals and provide latching operations to correspondingly output two latching signals according to signal levels of the two output signals;
wherein when the driving signal drives one of the complementary switches by the rising-edge manner, the corresponding latching signal is controlled at a high-level status and the other latching signal is simultaneously controlled at a low-level status so that the one of the complementary switches is turned on and the other of the complementary switches is turned off, thus preventing the at least one pair of complementary switches from a short through operation.

10. The bridge switch control circuit in claim 9, wherein the bridge switch control circuit further comprising:
two voltage amplifying units, each voltage amplifying unit configured to receives a drain-source voltage of the one of the complementary switches, amplifies the drain-source voltage, and produces an amplified drain-source voltage; and
two comparison units, each comparison unit configured to receive the amplified drain-source voltage and a reference voltage, compare the amplified drain-source voltage to the reference voltage, and produces a level signal; wherein the level signal is high-level when the amplified drain-source voltage is greater than or equal to the reference voltage, the level signal is low-level when the amplified drain-source voltage is less than the reference voltage.

11. The bridge switch control circuit in claim 9, wherein the two driving signals are a first driving signal and a second driving signal, and the two latching signals are a first latching signal and a second latching signal; when the first driving signal triggers the one of the complementary switches by the rising-edge manner, the first latching signal is controlled at a high-level status and the second latching signal is simultaneously controlled at a low-level status; when the first latching signal does not trigger the one of the complementary switches by the rising-edge manner, the first latching signal and the second latching signal are maintained at the low-level status and the high-level status; when the second driving signal triggers the other of the complementary switches by the rising-edge manner, the second latching signal is controlled at a high-level status and the first latching signal is simultaneously controlled at a low-level status; when the second latching signal does not trigger the other of the complementary switches by the rising-edge manner, the first latching signal and the second latching signal are maintained at the high-level status and the low-level status.

12. The bridge switch control circuit in claim 11, wherein the one pair of the complementary switches are configured to form a half-bridge circuit architecture, the two complementary switches are a first switch and a second switch; the first driving signal and the second driving signal are configured to drive the first switch and the second switch, respectively; when the first driving signal is at a high-level status and the second driving signal is at a low-level status, the first latching signal is controlled at the high-level status and the second latching signal is simultaneously controlled at the low-level status so as to turn on the first switch and turn off the second switch, thus preventing the first switch and the second switch from a short through operation.

13. The bridge switch control circuit in claim 11, wherein the one pair of the complementary switches are configured to form a half-bridge circuit architecture, the two switches are a first switch and a second switch; the first driving signal and the second driving signal are configured to drive the first switch and the second switch, respectively; when the second driving signal is at a high-level status and the first driving signal is at a low-level status, the second latching signal is controlled at the high-level status and the first latching signal is simultaneously controlled at the low-level status so as to turn on the second switch and turn off the first switch, thus preventing the second switch and the first switch from a short through operation.

14. The bridge switch control circuit in claim 11, wherein the two pairs of the complementary switches are configured to form a full-bridge circuit architecture, the four switches are a first switch, a second switch, a third switch, and a fourth switch; the first switch and the fourth switch are simultaneously turned on or turned off to form a first switch assembly, the second switch and the third switch are simultaneously turned on or turned off to form a second switch assembly; the first driving signal and the second driving signal are configured to drive the first switch assembly and the second switch assembly, respectively; when the first driving signal is at a high-level status and the second driving signal is at a low-level status, the first latching signal is controlled at the high-level status and the second latching signal is simultaneously controlled at the low-level status so as to turn on the first switch assembly and turn off the second switch assembly, thus preventing the first switch assembly and the second switch assembly from a short through operation.

15. The bridge switch control circuit in claim 11, wherein the two pairs of the complementary switches are configured to form a full-bridge circuit architecture, the four switches are a first switch, a second switch, a third switch, and a fourth switch; the first switch and the fourth switch are simultaneously turned on or turned off to form a first switch assembly, the second switch and the third switch are simultaneously turned on or turned off to form a second switch assembly; the first driving signal and the second driving signal are configured to drive the first switch assembly and the second switch assembly, respectively; when the second driving signal is at a high-level status and the first driving signal is at a low-level status, the second latching signal is controlled at the high-level status and the first latching signal is simultaneously controlled at the low-level status so as to turn on the second switch assembly and turn off the first switch assembly, thus preventing the second switch assembly and the first switch assembly from a short through operation.

16. The bridge switch control circuit in claim 9, wherein dead times are provided between the at least one pair of complementary switches which are turned on and turned off.

17. The bridge switch control circuit in claim 9, wherein each of the complementary switches is a metal-oxide-semiconductor field effect transistor (MOSFET) or an insulated gate bipolar transistor (IGBT).

18. The bridge switch control circuit in claim 9, wherein the latching unit is a NOR R-S latch, a NAND R-S latch, or a D latch.
